(19) United States
(12) Patent Application Publication
(10) Pub. No.: US 2024/0098962 A1
(43) Pub. Date: Mar. 21, 2024

(54) SEMICONDUCTOR DEVICE AND SEMICONDUCTOR MEMORY DEVICE

(71) Applicant: Kioxia Corporation, Tokyo (JP)

(72) Inventors: Daisuke WATANABE, Yokkaichi Mie (JP); Akifumi GAWASE, Kuwana Mie (JP); Takeshi IWASAKI, Kuwana Mie (JP); Kazuhiro KATONO, Yokkaichi Mie (JP); Yusuke MUTO, Yokkaichi Mie (JP); Yusuke MIKI, Yokkaichi Mie (JP); Akinori KIMURA, Yokkaichi Mie (JP)

(73) Assignee: Kioxia Corporation, Tokyo (JP)

(21) Appl. No.: 18/165,595

(22) Filed: Feb. 7, 2023

(30) Foreign Application Priority Data
Sep. 20, 2022 (JP) 2022-148926

(51) Int. Cl. H10B 10/00; H01L 29/786

(52) U.S. Cl. CPC H10B 10/125; H01L 29/78693

(57) ABSTRACT

A semiconductor device including a first electrode, a second electrode, an oxide semiconductor disposed between the first electrode and the second electrode, and a first oxide layer containing a predetermined element, oxygen, and an additional element and disposed between the first electrode and the oxide semiconductor, wherein the predetermined element is at least one of tantalum, boron, hafnium, silicon, zirconium, or niobium, and the additional element is at least one of phosphorus, sulfur, copper, zinc, gallium, germanium, arsenic, selenium, silver, indium, tin, antimony, tellurium, or bismuth.

### CROSS-REFERENCE TO RELATED APPLICATION(S)

This application is based upon and claims the benefit of priority from Japanese Patent Application No. 2022-148926, filed Sep. 20, 2022, the entire contents of which are incorporated herein by reference.

### FIELD

Embodiments described herein relate generally to a semiconductor device and a semiconductor memory device.

### BACKGROUND

Some semiconductor elements are formed from an oxide semiconductor.

### DESCRIPTION OF THE DRAWINGS

FIG. 1 is a circuit diagram illustrating a circuit configuration example of a memory cell array according to a first embodiment.

FIG. 2 is a schematic cross-sectional view illustrating a structure example of a semiconductor memory device according to the first embodiment and illustrates a part of a cross section parallel to a YZ plane.

FIG. 3 is a schematic cross-sectional view illustrating a semiconductor device according to a comparative example and illustrates a part of a cross section parallel to a YZ plane.

FIG. 4 is a schematic cross-sectional view illustrating a semiconductor device according to a second embodiment and illustrates a part of a cross section parallel to a YZ plane.

FIG. 5 is a schematic cross-sectional view illustrating a semiconductor device according to a third embodiment and illustrates a part of a cross section parallel to a YZ plane.

FIG. 6 is a schematic cross-sectional view illustrating a semiconductor device according to a fourth embodiment and illustrates a part of a cross section parallel to a YZ plane.

### DETAILED DESCRIPTION

A technique that can achieve favorable off-leakage current characteristics by preventing diffusion of oxygen in an oxide semiconductor and achieve an on-state current due to favorable conductivity has been required.

Embodiments provide a semiconductor device that can achieve favorable off-leakage current characteristics by preventing diffusion of oxygen in an oxide semiconductor and achieve an on-state current due to favorable conductivity and a semiconductor memory device.

In general, according to at least one embodiment, a semiconductor device includes a first electrode, a second electrode, an oxide semiconductor disposed between the first electrode and the second electrode, and a first oxide layer containing a predetermined element, oxygen, and an additional element and disposed between the first electrode and the oxide semiconductor, wherein the predetermined element is at least one of tantalum, boron, hafnium, silicon, zirconium, or niobium, and the additional element is at least one of phosphorus, sulfur, copper, zinc, gallium, germanium, arsenic, selenium, silver, indium, tin, antimony, tellurium, or bismuth.

According to at least one embodiment, a semiconductor device includes a first electrode, a second electrode, an oxide semiconductor disposed between the first electrode and the second electrode and the most containing an element as a first element among elements other than oxygen, and a first oxide layer disposed between the first electrode and the oxide semiconductor and the most containing an element as a second element among elements other than oxygen, wherein a bond-dissociation energy between the second element and oxygen is higher than a bond-dissociation energy between the first element and oxygen.

According to one embodiment, a semiconductor memory device includes the semiconductor device, a first capacitor electrode connected to the second electrode, a second capacitor electrode facing the first capacitor electrode, and a dielectric film disposed between the first capacitor electrode and the second capacitor electrode.

Hereinafter, embodiments will be described with reference to the accompanying drawings. For ease of understanding the description, the same components are given the same reference numerals in each drawing as much as possible, and duplicated description is omitted.

### First Embodiment

A configuration of a semiconductor memory device according to a first embodiment will be described. In each drawing, X, Y, and Z axes may be used. The X, Y, and Z axes form right-handed three-dimensional orthogonal coordinates. Hereinafter, the arrow direction of the X axis may be referred to as a +X-axial direction, and a direction opposite to the arrow direction may be referred to as a −X-axial direction. The same applies to the axes other than the X axis. Further, a +Z-axial direction and a −Z-axial direction may be referred to as “upward” and “downward”, respectively. Furthermore, a plane orthogonal to the X, Y, or Z axis may be referred to as a YZ plane, a ZX plane, or an XY plane, respectively.

The term “connection” as used herein includes not only physical connection but also electrical connection, and unless otherwise specified, includes not only direct connection but also indirect connection.

A semiconductor memory device 101 according to the first embodiment is an oxide semiconductor-random access memory (OS-RAM) and includes a memory cell array.

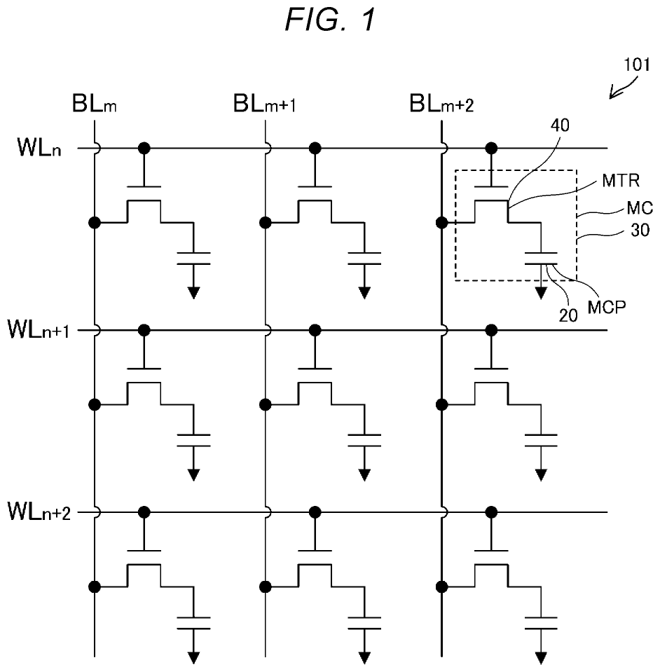

As illustrated in FIG. 1, the memory cell array includes a plurality of memory cells MC, a plurality of word lines WL, and a plurality of bit lines BL.

FIG. 1 illustrates, as an example of the word lines WL, a word line WLₙ, a word line WLₙ₊₁, and a word line WLₙ₊₂ (wherein n is an integer). FIG. 1 illustrates, as an example of the bit lines BL, a bit line BLₘ, a bit line BLₘ₊₁, and a bit line BLₘ₊₂ (wherein m is an integer). The number of memory cells MC is not limited to the number of memory cells MC illustrated in FIG. 1.

The memory cells MC are arranged, for example, in a matrix and form the memory cell array. Each of the memory cells MC includes a memory transistor MTR, which is a field effect transistor (FET), and a memory capacitor MCP.

A series of memory cells MC disposed in a row direction are connected to the word line WL (e.g., word line WLₙ) corresponding to a row (e.g., nth row) that belongs to the memory cells. A series of memory cells MC disposed in a column direction are connected to the bit line BL (e.g., bit line BLₘ₊₂) corresponding to a column (e.g., (m+2)th column) that belongs to the memory cells.

Specifically, the gate of the memory transistor MTR in each of the memory cells MC is connected to the word line WL corresponding to a row that belongs to each of the memory cells MC. One of the source or the drain of the memory transistor MTR is connected to the bit line BL corresponding to a column that belongs to each of the memory cells MC.

One electrode of the memory capacitor MCP in each of the memory cells MC is connected to the other of the source or the drain of the memory transistor MTR in each of the memory cells MC. The other electrode in each of the memory cells MC is connected to a power supply line (not illustrated) for supplying a specific potential.

The memory cells MC each accumulate a charge in the memory capacitor MCP by applying a current through the corresponding bit line BL according to switching of the memory transistor MTR based on the potential of the corresponding word line WL, resulting in storage of data.

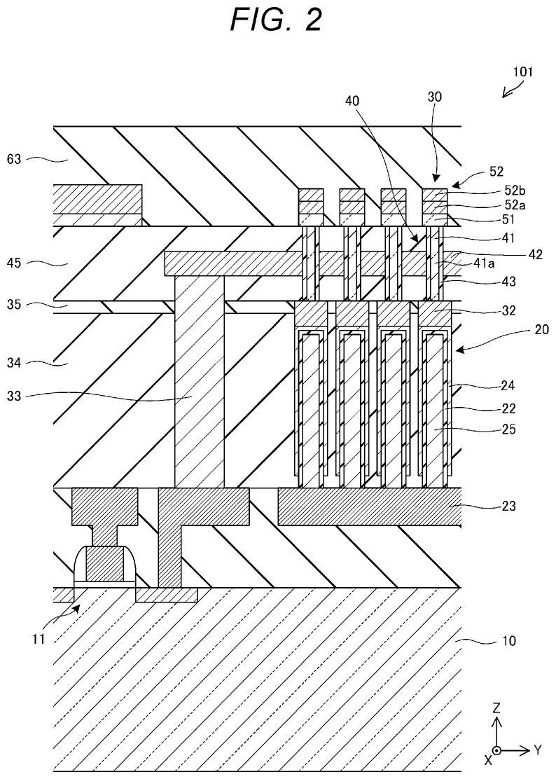

As illustrated in FIG. 2, the semiconductor memory device 101 includes a semiconductor substrate 10, a circuit 11, a capacitor 20, a semiconductor device 30, a conductor 33, and insulating layers 34, 35, 45, and 63.

The capacitor 20 includes an insulating film 22 (dielectric film), a conductor 23, and a first capacitor electrode 24 and a second capacitor electrode 25 that face each other through the insulating film 22.

The semiconductor device 30 includes an electric field effect transistor 40 (semiconductor element), a conductive oxide layer 32 (second electrode) disposed under the electric field effect transistor 40, and an oxide selector 51 (first oxide layer) and a conductive layer 52 (first electrode) that are disposed above the electric field effect transistor 40. The conductive layer 52 includes a TiN layer 52a and a tungsten layer 52b disposed on the TiN layer 52a.

The electric field effect transistor 40 includes an oxide semiconductor layer 41 (metal oxide semiconductor) corresponding to a channel, a conductive layer 42 (gate electrode) corresponding to a gate electrode, and an insulating layer 43 (insulating film) that is disposed between the conductive layer 42 and the oxide semiconductor layer 41 and corresponds to a gate insulating film.

The circuit 11 constitutes a peripheral circuit including a decoder for selecting a predetermined memory cell MC from the memory cells MC (the semiconductor device 30) in the semiconductor memory device 101, a sense amplifier connected to the bit line BL, a register of SRAM, and the like. The circuit 11 may include a CMOS circuit having an electric field effect transistor including a P-channel field effect transistor (Pch-FET) and an N-channel field effect transistor (Nch-FET) that are formed by a CMOS process.

The electric field effect transistor in the circuit 11 can be formed from the semiconductor substrate 10 such as a single crystal silicon substrate. The Pch-FET and the Nch-FET are a so-called lateral electric field effect transistor that has a channel region, a source region, and a drain region in the semiconductor substrate 10, and a channel through which carriers flow in the X- or Y-axial direction substantially parallel to the surface of the semiconductor substrate 10 at a region adjacent to the surface of the semiconductor substrate 10. The semiconductor substrate 10 may have a P- or N-type conductivity type. FIG. 2 illustrates an example of the electric field effect transistor in the circuit 11 for convenience.

The capacitor 20 is the memory capacitor MCP in each of the memory cells MC (see FIG. 1). FIG. 2 illustrates four capacitors 20, but the number of capacitors 20 is not limited to four.

In at least one embodiment, the capacitor 20 is disposed above the semiconductor substrate 10 (that is a region located above the surface of the semiconductor substrate 10. Herein, above means a direction (+Z-axial direction) apart away from the surface of the semiconductor substrate 10). The first capacitor electrode 24 in the capacitor 20 is connected to the conductive oxide layer 32. The second capacitor electrode 25 corresponding to the second capacitor electrode in the capacitor 20 faces the first capacitor electrode 24. The insulating film 22 is disposed between the first capacitor electrode 24 and the second capacitor electrode 25.

The capacitor 20 is a three-dimensional capacitor such as a cylinder-type capacitor. As the capacitor in the embodiment, another capacitor that accumulates a charge may be adopted. The second capacitor electrode 25 is disposed above the conductor 23 and is in contact with the upper end surface of the conductor 23. The upper end surface and the side surfaces of the second capacitor electrode 25 are covered with the insulating film 22. The first capacitor electrode 24 is disposed under the conductive oxide layer 32 and is in contact with the lower end surface of the conductive oxide layer 32. The upper end surface and a part of side upper surfaces of the insulating film 22 are covered with the first capacitor electrode 24.

The insulating film 22 may contain a material such as hafnium oxide. The conductor 23, the first capacitor electrode 24, and the second capacitor electrode 25 may contain a material such as tungsten (W) and titanium nitride (TiN).

The conductor 33 includes wiring that electrically connects the circuit 11 to the semiconductor device 30. The conductor 33 may include via wiring. For example, the conductor 33 includes via wiring that extends in the Z-axial direction and connects the word line WL to the circuit 11 disposed on the semiconductor substrate 10 as illustrated in FIG. 2. The conductor 33 contains, for example, copper.

The insulating layer 34 is disposed between the capacitor 20 and another capacitor 20. The insulating layer 34 is, for example, a silicon oxide film containing silicon and oxygen.

The insulating layer 35 is disposed above the insulating layer 34. The insulating layer 35 is, for example, a silicon nitride film containing silicon and nitrogen.

The semiconductor device 30 is disposed above the capacitor 20. The conductive oxide layer 32 in the semiconductor device 30 is disposed above the first capacitor electrode 24. The conductive oxide layer 32 contains a metal oxide such as an indium-tin-oxide (ITO).

The electric field effect transistor 40 corresponds to the memory transistor MTR in each of the memory cells MC (see FIG. 1). The electric field effect transistor 40 is disposed above the conductive oxide layer 32.

The oxide semiconductor layer 41 in the electric field effect transistor 40 is in contact with each of the oxide selector 51 and the conductive oxide layer 32. The oxide semiconductor layer 41 is located in a direction (corresponding to the +Z-axial direction, and may be referred to as upward) away from the semiconductor substrate 10 relative to the conductive oxide layer 32. The oxide selector 51 is located in a direction (corresponding to the +Z-axial direction and may be referred to as upward) away from the semiconductor substrate 10 relative to the oxide semiconductor layer 41. Due to this configuration, the electric field effect transistor 40 is a so-called vertical transistor having a channel extending in the Z-axial direction (first direction) substantially perpendicular to the surface of the semiconductor substrate 10.

The oxide semiconductor layer 41 is a column extending in the Z-axial direction (first direction). The oxide semiconductor layer 41 forms a channel of the electric field effect transistor 40. The oxide semiconductor layer 41 has an amorphous structure.

The oxide semiconductor layer 41 is a semiconductor in which oxygen vacancy acts as a donor. The oxide semiconductor layer 41 contains, as a metal element, indium (In), zinc (Zn), and gallium (Ga). Specifically, the oxide semiconductor layer 41 is formed from an oxide of indium, gallium, and zinc, that is, InGaZnO (IGZO).

One end in the Z-axial direction (e.g., one of two end surfaces in the Z-axial direction) of the oxide semiconductor layer 41 is in contact with the oxide selector 51, and the other end in the Z-axial direction (e.g., the other of the two end surfaces in the Z-axial direction) of the oxide semiconductor layer 41 is in contact with the conductive oxide layer 32. One end in the +Z-axis direction of the oxide semiconductor layer 41 is connected to the conductive layer 52 through the oxide selector 51 and functions as one of the source or the drain of the electric field effect transistor 40. The other end in the −Z-axis direction of the oxide semiconductor layer 41 is connected to the conductive oxide layer 32 and functions as the other of the source or the drain of the electric field effect transistor 40. The side surface of the oxide semiconductor layer 41 may be in contact with at least one of the oxide selector 51 or the conductive oxide layer 32.

The conductive oxide layer 32 is disposed between the first capacitor electrode 24 in the capacitor 20 and the oxide semiconductor layer 41 in the electric field effect transistor 40 and functions as the other of the source electrode or the drain electrode of the electric field effect transistor 40. Since the conductive oxide layer 32 contains a metal oxide like the oxide semiconductor layer 41 in the electric field effect transistor 40, the contact resistance between the electric field effect transistor 40 and the conductive oxide layer 32 can be reduced.

The conductive layer 42 faces the oxide semiconductor layer 41. The insulating layer 43 is disposed between the oxide semiconductor layer 41 and the conductive layer 42. The conductive layer 42 is located in a second direction intersecting with the Z-axial direction with respect to the oxide semiconductor layer 41. A first portion 41a disposed in the oxide semiconductor layer 41 and between the oxide selector 51 and the conductive oxide layer 32 is in contact with the insulating layer 43, and the insulating layer 43 is in contact with the conductive layer 42.

In the embodiment, the conductive layer 42 extends in the Y-axial direction and surrounds the oxide semiconductor layer 41. The conductive layer 42 is superimposed on the oxide semiconductor layer 41 with the insulating layer 43 interposed therebetween with respect to the XY plane. The conductive layer 42 constitutes the gate electrode of the electric field effect transistor 40 and functions as the word line WL. The conductive layer 42 contains, for example, a metal, a metal compound, or a semiconductor. The conductive layer 42 contains, for example, at least one material selected from the group consisting of tungsten, titanium (Ti), titanium nitride, molybdenum (Mo), cobalt (Co), and ruthenium (Ru). The conductive layer 42 is connected to the conductor 33.

The insulating layer 43 is disposed between the oxide semiconductor layer 41 and the conductive layer 42 with respect to the XY plane. The insulating layer 43 forms a gate insulating film of the electric field effect transistor 40. The insulating layer 43 contains, for example, silicon, oxygen, or nitrogen.

The electric field effect transistor 40 is a so-called surrounding gate transistor (SGT) in which the gate electrode surrounds a channel. Due to the SGT, the area of the semiconductor memory device can be reduced.

An electric field effect transistor having a channel layer containing an oxide semiconductor has a lower off-leakage current than the electric field effect transistor disposed above the semiconductor substrate 10. For example, data stored in the memory cells MC can be stored for a long time, and therefore the number of refresh operations can be reduced. The electric field effect transistor having a channel layer containing an oxide semiconductor can be formed by a low-temperature process, and therefore the application of heat stress to the capacitor 20 can be prevented.

For example, the insulating layer 45 is disposed between a plurality of the electric field effect transistors 40. The insulating layer 45 is, for example, a silicon oxide film containing silicon and oxygen.

The oxide selector 51 is in contact with the upper end surface of the oxide semiconductor layer 41. The oxide selector 51 contains an oxide and an additional element.

The oxide contains a predetermined element and oxygen. The predetermined element is at least one of tantalum (Ta), boron (B), hafnium (Hf), silicon (Si), zirconium (Zr), or niobium (Nb). The additional element is at least one of phosphorus (P), sulfur (S), copper (Cu), zinc (Zn), gallium (Ga), germanium (Ge), arsenic (As), selenium (Se), silver (Ag), indium (In), tin (Sn), antimony (Sb), tellurium (Te), or bismuth (Bi).

The bond-dissociation energy between a second element and oxygen contained in the oxide selector 51 is higher than the bond-dissociation energy between a first element and oxygen contained in the oxide semiconductor layer 41. Herein, the first element is an element that is the most contained in the oxide semiconductor layer 41 among elements other than oxygen. The second element is an element that is the most contained in the oxide selector 51 among elements other than oxygen.

In at least one embodiment, the first element is, for example, tin, indium, gallium, or zinc. The bond-dissociation energies of a Sn—O bond, an In—O bond, and a Ga—O bond are 528, 346, and 374 kJ/mol, respectively. The bond-dissociation energy of a Zn—O bond is 250 kJ/mol or less.

The bond-dissociation energy between the second element and oxygen is 700 kJ/mol or more. In the embodiment, the second element is, for example, tantalum, boron, hafnium, silicon, zirconium, or niobium. The bond-dissociation energies of a Ta—O bond, a B—O bond, a Hf—O bond, a Si—O bond, a Zr—O bond, and a Nb—O bond are 839, 809, 801, 800, 766, and 727 kJ/mol, respectively.

It is preferable that the bond-dissociation energy between the second element and oxygen be more than two times the bond-dissociation energy between the first element and oxygen. Specifically, it is preferable that the first element be indium, gallium, or zinc and the second element be silicon.

The value obtained by dividing the atomic percent of the additional element contained in the oxide selector 51 by the atomic percent of the most contained element that is at least one among tantalum, boron, hafnium, silicon, zirconium, and niobium contained in the oxide in the oxide selector 51 is preferably 0.4 or less.

Specifically, when the additional element is arsenic and the element the most contained in the oxide in the oxide selector 51 is silicon, the value obtained by dividing the atomic percent of arsenic by the atomic percent of silicon is preferably 0.4 or less.

The conductive layer 52 functions as one of the source electrode or the drain electrode of the electric field effect transistor 40. The conductive layer 52 is disposed above at least one part of the oxide selector 51 and is in contact with the oxide selector 51. The conductive layer 52 forms an electrode electrically connected to the bit line BL not illustrated. The conductive layer 52 is electrically connected to the sense amplifier in the circuit 11 through the bit line BL. The conductive layer 52 contains a metal element. In the embodiment, the TiN layer 52a in the conductive layer 52 contains TiN. The TiN layer 52a may be a conductive layer containing an element other than TiN. The tungsten layer 52b contains tungsten. The tungsten layer 52b may be a conductive layer containing an element other than tungsten. The configuration of the conductive layer 52 is not limited to a configuration including two layers: the TiN layer 52a and the tungsten layer 52b. The conductive layer 52 may include three layer or more or be formed from a single layer.

For example, the insulating layer 63 is disposed between a stacked body containing the oxide selector 51 and the conductive layer 52 and an adjacent stacked body similarly containing the oxide selector 51 and the conductive layer 52. The insulating layer 63 is, for example, a silicon oxide film containing silicon and oxygen.

The oxide selector 51 acts as a selector. Herein, the selector is an element formed from a material having a property in which a current hardly flows due to relatively high resistance with a low voltage applied to one end and another end and a current flows due to relatively low resistance with a high voltage applied to the end and the other end. The voltage at which the resistance value varies may be referred to as threshold voltage. Therefore, when the voltage applied to the end and the other end of the oxide selector 51 is equal to or lower than the threshold voltage, the resistance between the end and the other end of the oxide selector 51 is high, and a current hardly flows.

In contrast, when the voltage applied to the end and the other end of the oxide selector 51 is higher than the threshold voltage, the resistance between the end and the other end of the oxide selector 51 is low, and a current flows.

In the embodiment, when the voltage applied to the ends in the Z-axial direction of the oxide selector 51 is equal to or lower than the threshold voltage, a current hardly flows through the oxide selector 51. When the voltage is higher than the threshold voltage, a current flows through the oxide selector 51.

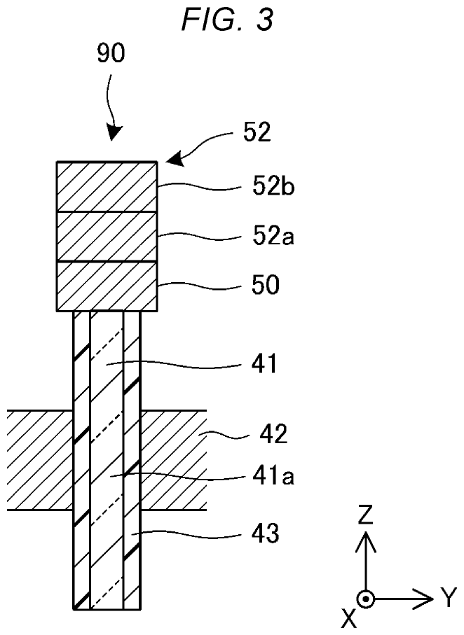

FIG. 3 illustrates a semiconductor device 90 according to a comparative example. As illustrated in FIG. 3, the semiconductor device 90 according to the comparative example is different from the semiconductor device 30 according to the embodiment in that instead of the oxide selector 51, an ITO layer 50 is contained. In the same configuration of the semiconductor device 90 as that of the semiconductor device 30, the same reference numerals as those of the semiconductor device 30 are used, and the description is omitted.

When a heat energy is applied by a heating treatment (annealing treatment) in a production process of the semiconductor device 90, oxygen in the ITO layer 50 may be diffused in the TiN layer 52a while oxygen in the oxide semiconductor layer 41 is diffused in the ITO layer 50.

Since oxygen vacancy in the oxide semiconductor layer 41 functions as a donor, the amount of oxygen vacancy needs to be appropriately controlled. Therefore, when the oxygen vacancy is excessively produced in the oxide semiconductor layer 41, the electric properties of the oxide semiconductor layer 41 approach those of a metal, to lose semiconductor properties.

In particular, when the amount of oxygen vacancy in the oxide semiconductor layer 41 is appropriate, the oxide semiconductor layer 41 is in an off state in which a current does not flow through the oxide semiconductor layer 41 with a gate voltage not applied to the conductive layer 42. When the gate voltage is increased to a threshold voltage (hereinafter sometimes referred to as Vth), a current starts to flow through the oxide semiconductor layer 41, to switch to an on state.

However, when the oxygen vacancy is excessively produced in the oxide semiconductor layer 41, Vth is shifted to negative Vth, and a current may flow through the oxide semiconductor layer 41 even under a low gate voltage (for example, ground voltage). That is, the off-leakage current characteristics of the oxide semiconductor layer 41 are deteriorated.

When oxygen is excessively diffused in the TiN layer 52a, an oxidation layer in which a parasitic resistance value is high is formed in the TiN layer 52a. Depending on the oxygen concentration in the ITO layer 50 that is close to a metal, contact resistance may be increased due to a Schottky barrier between the ITO layer 50 and the oxide semiconductor layer 41. Therefore, an on-state current flowing through the oxide semiconductor layer 41 when the oxide semiconductor layer 41 is in an on state (hereinafter which may be referred to as Ion) may be decreased.

In constant, in the semiconductor device 30 illustrated in FIG. 2, the bond-dissociation energy between oxygen and the element other than oxygen in the oxide contained in the oxide selector 51 (hereinafter which may be referred to as oxygen-bond-dissociation energy) is high. Therefore, diffusion of oxygen contained in the oxide selector 51 in the TiN layer 52a and diffusion of oxygen contained in the oxide semiconductor layer 41 in the oxide selector 51 can be prevented during a heating treatment.

Thus, the oxygen vacancy in the oxide semiconductor layer 41 can be reduced, to prevent shifting of Vth of the oxide semiconductor layer 41 to negative Vth. Accordingly, favorable off-leakage current characteristics can be achieved.

Further, formation of the oxidation layer in the TiN layer 52a and an increase in resistance value due to the insulating barrier can be prevented, to prevent a decrease in Ion. Accordingly, an on-state current can be achieved due to favorable conductivity.

### Second Embodiment

A semiconductor device 30a according to a second embodiment will be described. A description of a common content between the first embodiment and the following embodiments is omitted, and only a different content will be described. In particular, every embodiment does not refer to the same operation and effect based on the same configuration.

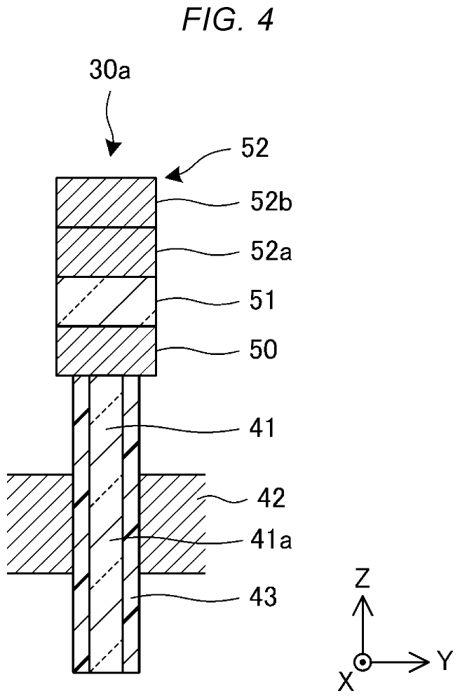

As illustrated in FIG. 4, the semiconductor device 30a is different from the semiconductor device 30 according to the first embodiment in that the ITO layer 50 (first oxide electrode) is further disposed between the oxide selector 51 and the oxide semiconductor layer 41 in comparison with the semiconductor device 30 illustrated in FIG. 2.

For example, when the oxide selector 51 is in direct contact with the oxide semiconductor layer 41, contact resistance may be increased due to a Schottky barrier and the like. In the semiconductor device 30a, the ITO layer 50 is disposed between the oxide selector 51 and the oxide semiconductor layer 41, and therefore the contact resistance can be decreased.

Due to the configuration in which the oxide selector 51 with a high bond-dissociation energy is disposed between the ITO layer 50 and the TiN layer 52a, diffusion of oxygen in the ITO layer 50 in the TiN layer 52a can be prevented during a heating treatment.

Thus, an increase in resistance value due to the formation of the oxidation layer in the TiN layer 52a can be prevented, to prevent a decrease in Ion. Accordingly, an on-state current can be achieved due to favorable conductivity.

### Third Embodiment

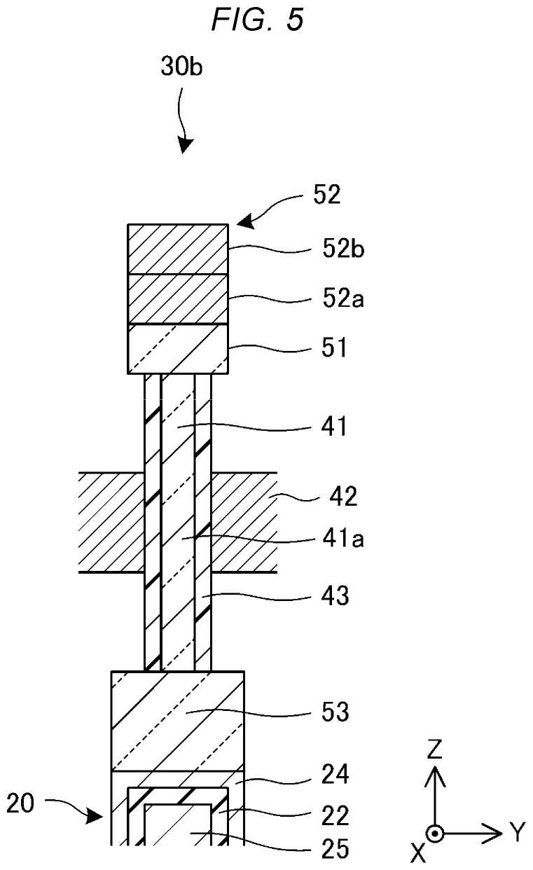

A semiconductor device 30b according to a third embodiment will be described. As illustrated in FIG. 5, the semiconductor device 30b is different from the semiconductor device 30 according to the first embodiment in that instead of the conductive oxide layer 32, an oxide selector 53 (second oxide layer) is disposed in comparison with the semiconductor device 30 illustrated in FIG. 2. In the semiconductor device 30b, the first capacitor electrode 24 corresponds to a “second electrode”.

The oxide selector 53 has an upper end surface that is in contact with the lower end surface of the oxide semiconductor layer 41 and a lower end surface that is in contact with the upper end surface of the first capacitor electrode 24. The oxide selector 53 acts as a selector.

The oxide selector 53 contains an oxide and an additional element. The oxide and the additional element contained in the oxide selector 53 are the same as the oxide and the additional element contained in the oxide selector 51, respectively.

Specifically, the oxide contained in the oxide selector 53 contains a predetermined element and oxygen. The predetermined element is at least one of tantalum, boron, hafnium, silicon, zirconium, or niobium. The additional element contained in the oxide selector 53 is at least one of phosphorus, sulfur, copper, zinc, gallium, germanium, arsenic, selenium, silver, indium, tin, antimony, tellurium, or bismuth.

The bond-dissociation energy between a third element and oxygen contained in the oxide selector 53 is higher than the bond-dissociation energy between the first element and oxygen contained in the oxide semiconductor layer 41. Herein, the third element is an element that is the most contained in the oxide selector 53 among elements other than oxygen.

In the embodiment, the bond-dissociation energy between the third element and oxygen is 700 kJ/mol or more. The third element is, for example, tantalum, boron, hafnium, silicon, zirconium, or niobium.

It is preferable that the bond-dissociation energy between the third element and oxygen be more than two times the bond-dissociation energy between the first element and oxygen. Specifically, it is preferable that the first element be indium, gallium, or zinc and the third element be silicon.

The value obtained by dividing the atomic percent of the additional element contained in the oxide selector 53 by the atomic percent of the most contained element that is at least one among tantalum, boron, hafnium, silicon, zirconium, and niobium contained in the oxide in the oxide selector 53 is preferably 0.4 or less.

The composition of the oxide selector 53 may be the same as or different from the composition of the oxide selector 51.

A configuration in which the oxide selectors 51 and 53 are disposed at both ends of the oxide semiconductor layer 41 like the semiconductor device 30b is described, but a configuration is not limited to this configuration. For example, the configuration may be a configuration in which the oxide selector 51 is not disposed and the oxide selector 53 is disposed only under the oxide semiconductor layer 41. For example, the ITO layer may be disposed between the oxide selector 51 and the oxide semiconductor layer 41.

### Fourth Embodiment

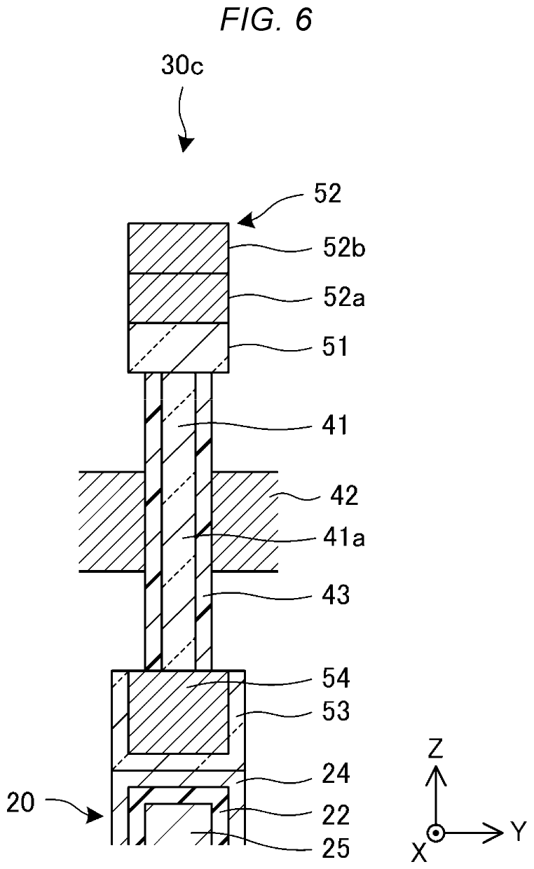

A semiconductor device 30c according to a fourth embodiment will be described. As illustrated in FIG. 6, the semiconductor device 30c is different from the semiconductor device 30b according to the third embodiment in that an ITO layer 54 (second oxide electrode) is further disposed between the oxide selector 53 and the oxide semiconductor layer 41 in comparison with the semiconductor device 30b illustrated in FIG. 5.

The ITO layer 54 has an upper end surface that is in contact with the lower end surface of the oxide semiconductor layer 41. The lower end surface and the side surfaces of the ITO layer 54 are covered with the oxide selector 53.

For example, when the oxide selector 53 is in direct contact with the oxide semiconductor layer 41, contact resistance may be increased due to a Schottky barrier and the like. In the semiconductor device 30c, the ITO layer 54 is disposed between the oxide selector 53 and the oxide semiconductor layer 41, and therefore the contact resistance can be decreased.

Due to the configuration in which the oxide selector 53 with a high bond-dissociation energy is disposed between the ITO layer 54 and the first capacitor electrode 24, diffusion of oxygen in the ITO layer 54 in the first capacitor electrode 24 can be prevented during a heating treatment.

Thus, an increase in resistance value due to the formation of the oxidation layer in the first capacitor electrode 24 can be prevented, to prevent a decrease in Ion. Accordingly, an on-state current can be achieved due to favorable conductivity.

The ITO layer 50 may be disposed between the oxide selector 51 and the oxide semiconductor layer 41.
(a) In the embodiment, the configuration in which the electric field effect transistor 40 is SGT is described, but a configuration is not limited to this configuration. The electric field effect transistor 40 may have another structure such as a bottom gate structure.
(b) In the embodiment, the configuration in which the electric field effect transistor 40 is used in OS-RAM is described, but a configuration is not limited to this configuration. The electric field effect transistor 40 can be adopted for a semiconductor device other than OS-RAM.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a second electrode;
an oxide semiconductor disposed between the first electrode and the second electrode; and
a first oxide selector containing a predetermined element, oxygen, and an additional element, the first oxide selector disposed between the first electrode and the oxide semiconductor,
wherein the predetermined element is at least one of tantalum, boron, hafnium, silicon, zirconium, or niobium, and the additional element is at least one of phosphorus, sulfur, copper, zinc, gallium, germanium, arsenic, selenium, silver, indium, tin, antimony, tellurium, or bismuth.

2. A semiconductor device comprising:
a first electrode;
a second electrode;
an oxide semiconductor disposed between the first electrode and the second electrode, the oxide semiconductor including a first element that is the most contained in the oxide semiconductor among elements other than oxygen; and
a first oxide selector disposed between the first electrode and the oxide semiconductor, the first oxide selector including a second element that is the most contained in the first oxide selector among elements other than oxygen,
wherein a bond-dissociation energy between the second element and oxygen is higher than a bond-dissociation energy between the first element and oxygen.

3. The semiconductor device according to claim 2, wherein the bond-dissociation energy between the second element and oxygen is 700 kJ/mol or more.

4. The semiconductor device according to claim 2, wherein the bond-dissociation energy between the second element and oxygen is more than two times the bond-dissociation energy between the first element and oxygen.

5. The semiconductor device according to claim 1, wherein a first value is 0.4 or less, the first value obtained by dividing (i) an atomic percent of the additional element contained in the first oxide selector by (ii) an atomic percent of the most contained element, contained in the first oxide selector, that is at least one among tantalum, boron, hafnium, silicon, zirconium, or niobium.

6. The semiconductor device according to claim 1, further comprising:
a first oxide electrode disposed between the first oxide selector and the oxide semiconductor.

7. The semiconductor device according to claim 1, further comprising:
a second oxide selector containing (i) at least one of tantalum, boron, hafnium, silicon, zirconium, or niobium, (ii) oxygen, and (iii) at least one of phosphorus, sulfur, copper, zinc, gallium, germanium, arsenic, selenium, silver, indium, tin, antimony, tellurium, or bismuth, the second oxide selector disposed between the second electrode and the oxide semiconductor.

8. The semiconductor device according to claim 2, further comprising:
a second oxide selector having a most containing element as a third element among elements other than oxygen, the second oxide selector being disposed between the second electrode and the oxide semiconductor, wherein a bond-dissociation energy between the third element and oxygen is higher than the bond-dissociation energy between the first element and oxygen.

9. The semiconductor device according to claim 7, further comprising:
a second oxide electrode disposed between the second oxide selector and the oxide semiconductor.

10. The semiconductor device according to claim 1, further comprising:
a gate electrode surrounding the oxide semiconductor; and
an insulating film disposed between at least a part of the oxide semiconductor and the gate electrode.

11. The semiconductor device according to claim 7, wherein the oxide semiconductor extends in a first direction, has an end in contact with the first oxide selector in the first direction, and has an end in contact with the second oxide selector in the first direction.

12. A semiconductor memory device comprising:
the semiconductor device according to claim 1;
a first capacitor electrode connected to the second electrode;
a second capacitor electrode facing the first capacitor electrode; and
a dielectric film disposed between the first capacitor electrode and the second capacitor electrode.

13. The semiconductor device according to claim 1, wherein the oxide semiconductor comprises a random access memory.

14. The semiconductor device according to claim 1, wherein the oxide semiconductor is formed of an amorphous material.

15. The semiconductor device according to claim 1, wherein the oxide semiconductor includes oxygen vacancies acting as a donor.

16. The semiconductor memory device according to claim 12, wherein the first capacitor electrode and the second capacitor electrode contain at least one of tungsten or titanium nitride.
